(19) United States
(12) Patent Application Publication
(10) Pub. No.: US 2007/0077134 A1
(43) Pub. Date: Apr. 5, 2007

(54) Vacuum handler systems and processes for flexible automation of semiconductor fabrication

(76) Inventor: Colin John Dickinson, San Jose, CA (US)

Correspondence Address: THE BOC GROUP, INC., 575 MOUNTAIN AVENUE, MURRAY HILL, NJ, 07974-2064, US

(21) Appl. No.: 11/239,968

(22) Filed: Sep. 30, 2005

(51) Int. Cl. H01L 21/677

(52) U.S. Cl. 414/217

(57) ABSTRACT

Apparatus and methods useful for flexible factory automation of semiconductor vacuum systems are presented, including a load lock accessible by robotic means located in a substrate handler connected to and positioned between the load lock and a vacuum process chamber. The substrate handler has a substrate storage position and a substrate active position, wherein the substrate handler is adapted to be isolated from the load lock when the load lock is pumped down, and a single vacuum pump is used to service both the load lock and the substrate handler.

### BACKGROUND OF THE INVENTION

The invention is generally related to the field of semiconductor manufacturing. More specifically, the invention relates to systems and processes for flexible automation of semiconductor fabrication.

Vacuum systems are ubiquitous in the semiconductor and flat panel display fabrication industries. The challenge for these industries is to increase productivity of the semiconductor tools (process chambers), including tools using vacuum processing. One approach is to cluster multiple vacuum process chambers around a central vacuum handler. Although this does have the advantage of utilizing one vacuum handler for multiple process chambers, there are significant disadvantages. First, when the vacuum handler experiences a problem and must be taken out of service, the entire cluster become unusable for processing substrates. Second, unless a manufacturer is willing to live with the first problem, one or more spare vacuum handlers must be available. This leads logically to the second main approach, having one load lock and vacuum handler for each process chamber. This approach solves the most glaring problem with the cluster approach, but at a major cost, since multiple vacuum pumps must be installed, two for each load lock/vacuum handler combination, as well as a vacuum pump for each process chamber. There have been recent efforts to overcome these disadvantages, but with limited success.

U.S. Pat. Pub. No. 20010041121A1 discloses a single chamber vacuum processing tool in which the vacuum process chamber is coupled to a load lock/transfer chamber (a chamber that functions both as a load lock and contains a substrate handler). A substrate handler transfers a substrate (preferably along a straight line) between the load lock/transfer chamber and the vacuum processing chamber. The load lock/transfer chamber may contain one or more substrate storage locations such that a first substrate may be stored therein while a second substrate is processed. Thus, the load lock/transfer chamber need only pump and vent between vacuum and atmospheric pressure once for every two substrates processed within the vacuum processing chamber. The substrate storage locations may be coupled to a temperature adjustment mechanism for heating and/or cooling a stored substrate. While this does reduce some equipment capital cost, there is an inherent increased risk that environmental contaminants will be transferred to or from the processing module, since there is no buffer between the process chamber and the load lock/transfer mechanism.

U.S. Pat. No. 6,609,869 discloses a substrate processing system including a substrate handling chamber and an integrated load lock chamber. The load lock chamber has a gated inlet for the transfer of a substrate into and out of the load lock chamber and a gated port for transferring a substrate between the load lock chamber and the substrate handling chamber. The substrate handling chamber includes a staging shelf that is positioned above the load lock chamber and a substrate handler for moving a substrate between the load lock chamber and the staging shelf. In use, a first substrate is placed at a load lock station that is located inside the load lock chamber. The first substrate is moved from the load lock station to a staging shelf located inside the substrate handling chamber. A second substrate is moved from a cooling station in the substrate handling chamber to the load lock station. A third substrate is moved from a substrate processing chamber to the cooling station. Preferably, after the third substrate is moved to the cooling station, the first substrate is moved from the staging shelf to the processing chamber. The second substrate is removed from the load lock chamber and the cycle is repeated. This three station system introduces a level of complexity, as well as an added space requirement for separate cooling and staging areas.

U.S. Pat. No. 6,860,711 discloses a semiconductor-manufacturing device equipped with a load lock chamber and a process chamber, which are directly connected, wherein a semiconductor wafer is transferred by a transferring arm provided inside the load lock chamber from the load lock chamber onto a susceptor provided inside the process chamber. The device includes a buffer mechanism for keeping a semiconductor wafer standing by inside the process chamber.

U.S. Pat. No. 6,663,333 discloses a load lock chamber assembly including a load lock chamber, a sub-chamber removably attached to the load lock chamber and a first robot arm having a primary pivot axis within the sub-chamber, wherein the first robot arm can move a substrate from a position approximately in a center of the load lock chamber to a position outside the load lock chamber.

U.S. Pat. No. 6,257,827 discloses a cluster method and apparatus using multiple load locks wherein a processed substrate is returned by an internal robot from one of its processing modules to a shelf or slot in a load lock from which the last substrate was removed for processing by the robot, rather than being returned to the original source shelf or slot from which it was removed for processing. Venting for one of the load locks is started as soon as the second load lock becomes the substrate source for the internal robot rather than waiting until the first load lock has been refilled with processed substrates.

U.S. Pat. No. 6,530,732 discloses a load lock and related method of handling a substrate involving placing a substrate onto a vertically movable poppet and moving the poppet between two vertically opposed subchambers such that in moving the poppet toward one of the subchambers, that subchamber is sealed to atmosphere. The two subchamber system allows one substrate to be placed into a buffer and another substrate to be cooled at the same time using a heat transfer device.

U.S. Pat. No. 6,315,512 discloses a workpiece handling system with dual load locks, a transport chamber and a process chamber. Workpieces may be retrieved from one load lock for processing at vacuum pressure, while workpieces are unloaded from the other load lock at the pressure of the surrounding environment. The transport chamber has a transport robot with two arms. Processed workpieces and new workpieces may be exchanged by a simple under/over motion of the two robot arms. The transport robot rotates about a central shaft to align with the load locks or the process chamber. The robot may also be raised or lowered to align the arms with the desired location to which workpieces are deposited or from which workpieces are retrieved. The two load locks may be positioned one above the other such that a simple vertical motion of the robot can be used to select between the two load locks.

Despite improvements in the art, the need remains for systems and processes to efficiently and safely increase productivity in semiconductor fabrication while minimizing installed and operating cost and complicated equipment, especially in view of the increasing demands of investors and the consuming public for greater efficiency, smaller electronic devices, and clean processing.

### SUMMARY OF THE INVENTION

In accordance with the present invention, apparatus and methods of use are presented which reduce or overcome many of the problems of previously known vacuum systems.

A first aspect of the invention relates to an apparatus for movement of substrates into and out of a vacuum processing chamber, the apparatus comprising:
a load lock for robotic introduction and removal of a semiconductor substrate;
a substrate vacuum handler fluidly connected to the load lock and positioned between the load lock and a vacuum process chamber, the vacuum handler having a substrate active position and a substrate storage position substantially vertically above the substrate active position; and
a robot positioned within the vacuum handler capable of accessing the load lock and the vacuum processing chamber and capable of vertical motion to move a substrate between the active position and the storage position.

Apparatus of the present invention may be portable, so that the apparatus may be installed in one location and then transferred to another location, either in the same plant, or different plant. Other embodiments of the present invention include apparatus wherein the vacuum handler includes a substrate holder at the substrate stand-by position, and apparatus wherein the substrate holder includes at least one horizontally moveable substrate holder element.

A second aspect of the present invention provides methods of processing substrates. For example, one method according to the present invention comprises the steps of:
placing a substrate into a load lock, the load lock connected to a vacuum handler, the load lock having a pressure greater than a pressure in the vacuum handler;
evacuating the load lock to the pressure of the vacuum handler using a vacuum pump;
accessing the substrate using a robot, the robot being internal to the vacuum handler;
moving the substrate into a substrate active position within the vacuum handler; and
moving the substrate into a vacuum process chamber using the robot.

Further embodiments of the present invention include methods wherein a processed substrate is removed from the process chamber by the robot prior to step (c) and moved by the robot to a substrate standby position inside the vacuum handler. The vacuum handler preferably comprises a substrate holder at the standby position, and the substrate holder moves to accept the processed substrate. The substrate holder may be a pair of substrate holder elements, and the elements may move horizontally to accept the processed substrate from the robot. After step (e) the robot may access the processed substrate in the standby position and move the processed substrate into the load lock, the robot then retracting back into the vacuum handler. The vacuum handler may be isolated from the load lock, then the load lock may be pressurized to atmospheric pressure and the processed substrate removed from the load lock. A new substrate is placed in the load lock, and the vacuum pump is engaged to pump down the load lock.

Another method according to the present invention includes staging a substrate for vacuum processing by a vacuum tool while another substrate is being processed. One such method comprises the steps of:
introducing a second substrate into a load lock while a first substrate is being processed by a vacuum tool, a vacuum handler connecting the load lock and the vacuum tool, the vacuum handler and vacuum tool being at a pressure lower than the load lock;
pumping down the load lock to a pressure substantially equal to the pressure of the vacuum handler using a vacuum pump;
accessing and removing the second substrate from the load lock using a robot, the robot positioned inside the vacuum handler;
moving the second substrate using the robot to a standby position in the vacuum handler, the standby position comprising a substrate holder;
moving the substrate holder to position the substrate holder in position to engage the second substrate; and
moving the robot to place the second substrate on the substrate holder in the standby position.

Alternative methods comprise moving the second substrate upward substantially vertically using the robot to the standby position in the vacuum handler; moving the substrate holder substantially horizontally to position the substrate holder in position to engage the second substrate; and lowering the robot substantially vertically to place the second substrate on the substrate holder in the standby position.

Further aspects and advantages of the invention will become apparent by reviewing the description of preferred embodiments that follows.

### BRIEF DESCRIPTION OF THE DRAWINGS

FIG. 1 is a block diagram of a prior art system architecture for semiconductor wafer processing.

FIG. 2 is a block diagram of a method and apparatus according to one embodiment of the present invention.

FIG. 3 is a detailed side view schematic block diagram of a method and apparatus according to one embodiment of the present invention.

### DESCRIPTION OF THE PREFERRED EMBODIMENTS

The term “vacuum handler”, as used herein refers to an apparatus and processes of the present invention, wherein a device that operates substantially under internal vacuum conditions, and has an internal chamber large enough to accommodate at least two substrates and a robot.

The term “robot” means an electromechanical component having the ability to move as described herein and grasp substrates. Robots are preferably operated by one or more controllers.

The term “modular” means the apparatus of the present invention constructed in standardized units and dimensions for flexibility and variety in use, and that may be disconnected from each other and used in other systems.

The present invention relates to vacuum handler apparatus and methods for flexible factory automation of semiconductor processes.

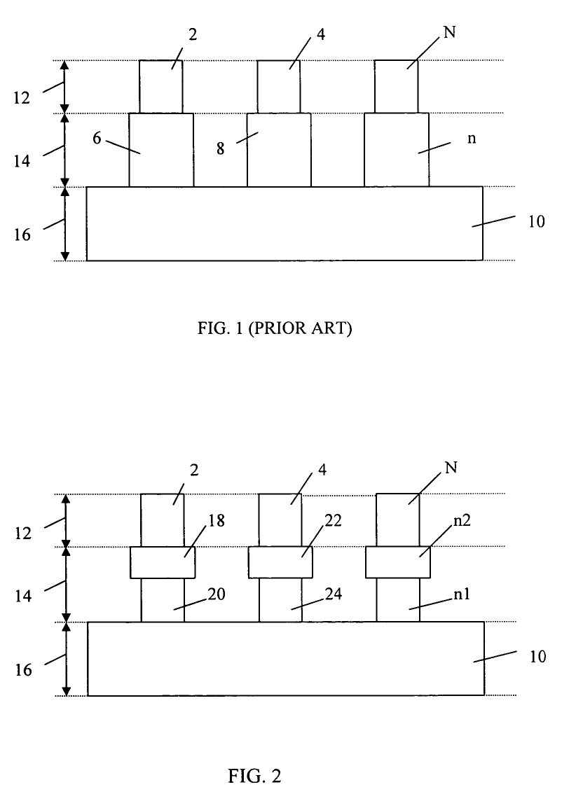

Referring to FIG. 1, there is illustrated schematically a previously known semiconductor equipment fabrication architecture. This architecture is rarely used in commercial semiconductor fabrication facilities due to throughput limitations of existing load locks, but is sufficient to illustrate the disadvantages of previous systems. FIG. 1 illustrates three zones 12, 14, and 16, which represent a tool bay, a load lock bay, and an equipment front end zone module, respectively. All of these features are known individually in the prior art. In this architecture an equipment front end module 10 services a plurality of load locks, two of which are shown as load locks 6 and 8, as well as a third load lock N associated with an “Nth” fabrication line. This architecture, using known load locks, may also include a vacuum handler (not illustrated) for each load lock. In this architecture, each load lock (and vacuum handler, if present) is associated with and serves only one tool. For example, load lock 6 services tool 2, and load lock 8 services tool 4, and load lock n services tool N. In situations where the tools are vacuum processing tools, which the present invention addresses, it is readily apparent that having one load lock for each process chamber solves the most glaring problem with the cluster approach, but at a major cost, since multiple vacuum pumps must be installed, two for each load lock/vacuum handler combination, as well as a vacuum pump for each process chamber.

FIG. 2 illustrates schematically the architecture of the fabrication lines when employing the methods and apparatus of the present invention. The tool bay 12 and equipment front end module 10 are unchanged from FIG. 1. Illustrated is a modified vacuum handler bay 14′in accordance with the present invention. Load locks 20, 24 and n1 serve flexible vacuum handlers 18, 22 and n2 respectively. In accordance with the invention, load locks 20 and 24 are preferably fast vacuum load locks, such as, but not limited to, the load lock described in U.S. Pat. No. 6,701,972, incorporated herein by reference in its entirety. This patent describes a system comprising a load lock apparatus having an interior configured to receive an object. At least one inlet valve may be flow coupled to the interior of the load lock apparatus, and at least one outlet valve may also be flow coupled to the interior of the load lock apparatus. A controller may be configured to selectively control opening and closing of the at least one inlet valve. The controller may be configured to open the at least one inlet valve and leave the one inlet valve open while the at least one outlet valve is closed for a predetermined period of time so as to substantially equilibrate pressure in the interior with pressure exterior of the load lock apparatus. The controller may also be configured to open the at least one outlet valve after the predetermined period of time to prevent over pressurization of the interior. As used herein “fast vacuum” means that the load lock is capable of being pumped down by a vacuum pump in much less time than a conventional load lock, primarily because of its small internal dimensions. This also means that a single vacuum pump may be used to service the vacuum requirements of the load lock and vacuum handler, and that the vacuum handler can be maintained in vacuum condition during the entire processing cycle. This differences represent significant advantages.

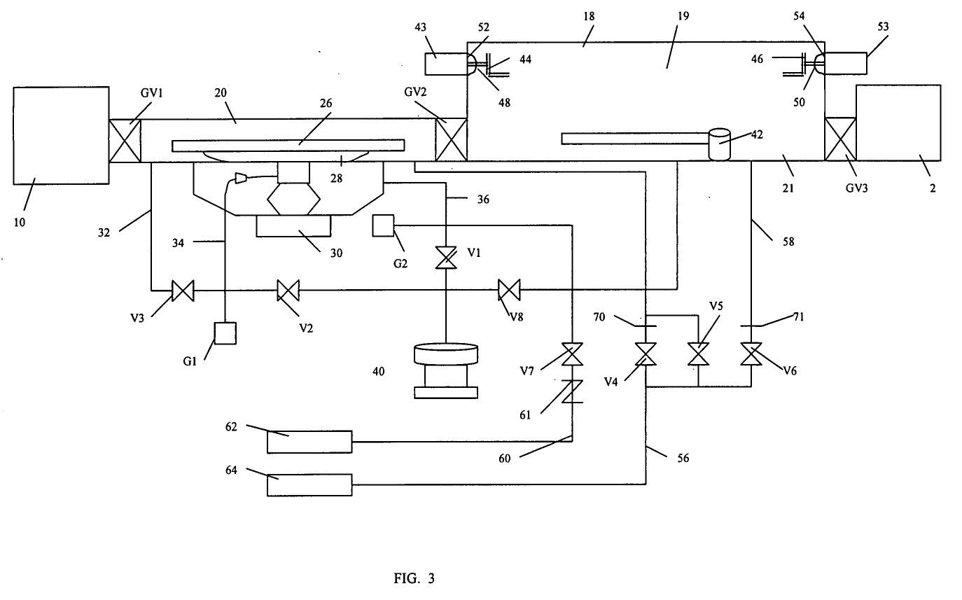

FIG. 3 illustrates one apparatus and method of the present invention in more detail. Illustrated schematically are a vacuum tool 2, a front end module 10, a vacuum handler 18, and a load lock 20. Gate valves GV1, GV2 and GV3 both fluidly connect and allow isolation of the various components. Also illustrated is a vacuum pump 40, connected to load lock 20 and vacuum handler 18 via various conduits and vacuum valves, as will be explained below.

Load lock 20 may be evacuated by starting vacuum pump 40 and closing valve V7 and opening valve V1 in conduit 36. Substrate 26, such as a semiconductor wafer is supported by and held down on a platen 28, by a vacuum hold down system 30 connected via conduit 34 to a vacuum pump 40. Valve V2 allows vacuum hold down to be applied and valve V3 allows the vacuum hold down pressure to be equalized through conduit 32 with pressure in load lock 20 such that the substrate may be released. Those skilled in the art will recognize that the illustrated vacuum hold down system 30 may be removed and the substrate supported and secured by other hold down systems or substrate holders known in the art. A gauge G1 allows monitoring of vacuum hold down pressure and gauge G2 allows monitoring of vacuum in load lock 20. Platens and vacuum hold down systems are known in the art and well explained in various reference materials, including U.S. Pat. No. 6,701,972, previously incorporated herein by reference in its entirety. An important feature of the apparatus and processes of the present invention is the means for evacuating, purging, and venting load lock 20 separately from vacuum handler 18. In the preferred embodiment illustrated in FIG. 3, valve V8 via conduit 38 allows vacuum handler 18 to be isolated and remain at process vacuum while load lock 20 is increased in pressure, vented, or at some other pressure for some other reason, such as atmospheric pressure for maintenance. This also allows load lock 20 and vacuum handler 18 to be serviced by the single vacuum pump 40.

A venting conduit 60 and valves are supplied to allow venting of load lock 20. Vent conduit 60 ties in to conduit 36, and a vacuum valve V7 and check valve 61 are connected to a vent 62. Gauge G2 allows monitoring vacuum pressure of both the vacuum produced by vacuum pump 40 and pressure in vent conduit 60.

Nitrogen, argon or other inert gas or gas mixture may be supplied to load lock 20 and vacuum handler 18 via a source of inert gas 64 via conduit 56. Valve V4 allows a low flow purge to be applied to load lock 20, valve V5 allows a high flow vent to be applied to load lock 20, and valve V6 allows low flow purge to be applied to vacuum handler 18 through conduit 58. In conjunction with valves V4 and V6, orifice or flow metering elements 70 and 71 are provided to allow control of purge flow rates to load lock 20 and vacuum handler 18.

The vacuum handler 18 has a substrate standby position in an upper region 19 of vacuum handler 18, and a substrate active position in a lower portion 21 of vacuum handler 18. A robot 42 is illustrated positioned in the lower region 21, but may also move into upper region 19 when required. Robot 42 is adapted to access and remove fresh substrates from load lock 20; place fresh substrates into upper region 19 of vacuum handler 18 for standby; access processed substrates in vacuum tool 2 and return them to load lock 20; and transport fresh substrates from upper region 19 of vacuum handler 18 into vacuum tool 2.

In the embodiment shown in FIG. 3, vacuum handler 18 includes at least two moveable substrate holders 43 and 53, adapted to move horizontally. Each holder 43 and 53 includes substrate holder elements 44 and 46, respectively, as well as means 48 and 50 for moving the substrate holders, in this case horizontally. The means for moving are preferably selected from hydraulic actuators, pneumatic actuators, rack and pinion devices, servo motors and the like. Sealing connections 52 and 54 are provided to allow movement of holders 43 and 53 in vacuum handler 18 without loss of vacuum. Sealing connections 52 and 54 may be bellows type seals, preferably stainless steel.

As mentioned above, preferred load locks for the inventive apparatus and processes, are of the fast vacuum type, affording quicker pump down time. Previously known load locks have pump down times from 760 mm to 10⁻⁶ torr of about 30 to 60 seconds. The fast vacuum load locks have typical pump down times of 2 seconds. However, any load lock may be used in the present invention. The load lock preferably can handle substrates of 300 millimeter diameter or larger, and may be constructed of stainless steel, for example types 304L and 316L, preferably electropolished stainless steel. The load locks used in the present invention preferably do not have heating and cooling facilities, nor do they have installed robots, although the interior of the load lock is accessible by a robot from the vacuum handler. This allows for a much smaller size requirement, thus allowing for the fast pump down time. The load lock may have various ports as known in the industry, such as a turbo pumping port, a roughing port, a manipulation port, gas inlet and vent ports, an atmosphere switch port, a viewing port, a cleaning access port, and various gauge ports. A fast entry door is provided, and the door is preferably sealed with polymeric 0-ring seals typically used in the industry, preferably the polymer known under the trade designation “Viton”, which is a fluoroelastomer available commercially from DuPont Dow Elastomers.

Robots used in the present invention, and the moveable substrate holders or end effectors, may be configured from commercially available equipment from Brooks Automation, Newport, Asyst, and others.

Vacuum pumps used in the present invention are available form BOC Edwards, amongst others. The vacuum pump or pumps are chosen depending on ultimate pressure and pump down time desired. Dry pumps known under the trade names EPX and IPX would be a typical choice for a load lock, possessing vacuum performance and footprint suitable for a typical load lock application. For example, a vacuum pump known under the trade designation IPX180 would achieve evacuation to less than 1 torr in approximately two seconds when the load lock detailed in U.S. Pat. No. 6,701,972 is used.

Valves V1, V2, V3, and V8 in the embodiment illustrated in FIG. 3 are any valves suitable for vacuum system isolation applications, such as those known under the trade designation “Speedivalve”, available from BOC Edwards.

Valves V4, V5, V6, and V7 in the embodiment illustrated in FIG. 3 are any valve available for high purity gas delivery system applications, such as those known under the trade designation “Mega-One”, available from Fujikin Incorporated.

Gauges G1 andG2 in the embodiment illustrated in FIG. 3 may be selected from any vacuum gauge suitable for the application. Typical gauges used in load lock applications include Pirani gauges and capacitance manometers available from BOC Edwards, amongst others.

Gates valves GV1, GV2, and GV3 in the embodiment illustrated in FIG. 3 may be selected from those designed to allow wafer passage, such as those available from VAT Vakuumventile AG and other manufacturers.

In operation of the apparatus of FIG. 3, one method of the invention proceeds as follows. A wafer or substrate is in tool 2 being processed, the wafer having been previously received from vacuum handler 18 using robot 42. Gate valves GV1, GV2 and GV3 are closed. Gate valve GV1 is opened and a second wafer is introduced into load lock 20 while the first wafer is inside tool 2. Gate valve GV1 is closed. With gate valves GV1 and GV2 closed, load lock 20 is pumped down to the required base pressure of vacuum handler 18, typically about 1 torr. Gate valve GV2 is then opened and robot 42 reaches into load lock 20 and removes the second wafer from the load lock. Gate valve GV2 remains open. Robot 42 moves the second wafer vertically into storage or standby location 19, then moveable wafer holders 44 and 46 move horizontally to provide a location position for the second wafer. Robot 42 lowers to place the second wafer in standby region 19. Meanwhile, processing of the first wafer is completed in tool 2, gate valve GV3 is opened and robot 42 removes the first wafer from tool 2 and places it into load lock 20. Robot 42 retracts into vacuum handler 18 and gate valve GV2 is closed. Load lock 20 is vented to atmosphere by opening valves V5 and V7, and robot 42 raises and picks the second wafer from standby position 19, lowers and then places the second wafer into tool 2. Robot 42 then retracts and gate valve GV3 closes to complete the cycle.

The embodiments of the invention allow flexibility in designing systems and apparatus for high throughput semiconductor wafer processing. The substrates processed in the inventive apparatus and using the inventive methods may be routed to storage in the vacuum handler or directly to a vacuum process chamber or tool. In the case of semiconductor and flat panel display fabrication, the substrate may be fed to a any of a number of tools used in these arts. The semiconductor fabrication tool may be selected from etching tools including oxide, metal and dielectric; deposition tools including silicon CVD; tungsten back-etching, and the like.

It is anticipated that other embodiments and variations of the present invention will become readily apparent to the skilled artisan in the light of the foregoing description and examples, and it is intended that such embodiments and variations likewise be included within the scope of the invention as set out in the appended claims.

What is claimed is:

1. An apparatus for movement of substrates into and out of a processing chamber, the apparatus comprising:
a load lock for robotic introduction and removal of a semiconductor substrate;
a handler chamber fluidly connected to the load lock and positioned between the load lock and a processing chamber, the handler chamber including an active position and a storage position substantially vertically above the active position; and
a robot positioned within the handler chamber capable of accessing the load lock and the processing chamber and capable of vertical motion to move a substrate between the active position and the storage position.

2. The apparatus of claim 1, further including a vacuum pump connected to the load lock and the handler chamber, wherein the handler chamber is adapted to be isolated from the load lock when the load lock is pumped down by the vacuum pump.

3. The apparatus of claim 1, wherein the handler chamber includes a substrate holder at the storage position.

4. The apparatus of claim 3, wherein the substrate holder includes at least one horizontally moveable substrate holder element.

5. The apparatus of claim 1, wherein the apparatus is portable.

6. The apparatus of claim 1, further including multiple processing chambers.

7. The apparatus of claim 1, wherein the substrate is a semiconductor wafer.

8. An apparatus for the treatment of substrates, said apparatus comprising:
a load lock adapted to receive a substrate;
a processing chamber for treating a substrate;
a substrate handler located between and connected to the load lock and the processing chamber, the substrate handler including an active position and a storage position, the storage position substantially vertically above said active position; and
a robot located within said substrate handler and capable of transferring a substrate in at least the following ways:
from the load lock to the storage position;
from the storage position to the processing chamber; and
from the processing chamber to the load lock.

9. A method of processing substrates comprising the steps of:
placing a first substrate into a load lock, the load lock connected to a substrate handler;
evacuating the load lock and the substrate handler using a single vacuum pump;
moving the first substrate from the load lock to a storage position in the substrate handler using a robot that is internal to the substrate handler;
moving a second substrate from a process chamber to the load lock using the robot; and
moving the first substrate into the process chamber using the robot.

10. The method of claim 9, further comprising moving a substrate holder located at the storage position in order to accept the first substrate.

11. The method of claim 10, wherein the substrate holder comprises a pair of substrate holder elements, and the step of moving the substrate holder comprises moving the substrate holder elements horizontally.

12. The method of claim 9, further comprising retracting the robot into the substrate handler after the step of moving the first substrate into the process chamber.

13. The method of claim 9, further comprising isolating the load lock from the substrate holder after the step of moving the second substrate from the process chamber to the load lock; venting the load lock to atmospheric pressure; and
removing the second substrate from the load lock.

14. The method of claim 13, wherein the entire method is performed cyclically.

15. A method of staging a first substrate for processing by a vacuum tool while a second substrate is being processed by the tool, the method comprising:
introducing the first substrate into a load lock while the second substrate is being processed by the vacuum tool, wherein a substrate handler is located between and connected to the load lock and the vacuum tool, the substrate handler and the vacuum tool being at a pressure lower than the load lock;
pumping down the load lock to a pressure substantially equal to the pressure of the substrate handler using a vacuum pump;
removing the first substrate from the load lock using a robot, the robot positioned inside the substrate handler;
placing the first substrate into a storage position in the substrate handler using the robot;
moving at least one substrate holder element at the storage position to engage the first substrate in the storage position.

16. The method of claim 15, wherein the step of placing the first substrate into the storage position comprises moving the first substrate upward substantially vertically to the storage position using the robot.

17. The method of claim 15, wherein the step of moving at least one substrate holder element comprises moving the at least one substrate holder element substantially horizontally.

18. The method of claim 15, further comprising lowering the robot substantially vertically after the first substrate has been engaged by the at least one substrate holder element.
